(19) United States
(12) Patent Application Publication
(10) Pub. No.: US 2013/0021556 A1
(43) Pub. Date: Jan. 24, 2013

(54) DISPLAY DEVICE AND METHOD OF MANUFACTURING THE SAME

(71) Applicants: Hitoshi NAGATO, Tokyo (JP); Takashi MIYAZAKI, Kanagawa-ken (JP); Yutaka NAKAI, Kanagawa-ken (JP); Hajime YAMAGUCHI, Kanagawa-ken (JP); Koji SUZUKI, Kanagawa-ken (JP); Rei HASEGAWA, Kanagawa-ken (JP)

(72) Inventors: Hitoshi NAGATO, Tokyo (JP); Takashi MIYAZAKI, Kanagawa-ken (JP); Yutaka NAKAI, Kanagawa-ken (JP); Hajime YAMAGUCHI, Kanagawa-ken (JP); Koji SUZUKI, Kanagawa-ken (JP); Rei HASEGAWA, Kanagawa-ken (JP)

(73) Assignee: Kabushiki Kaisha Toshiba, Tokyo (JP)

(21) Appl. No.: 13/482,236

(22) Filed: May 29, 2012

(30) Foreign Application Priority Data
Jul. 19, 2011 (JP) 2011-158477

(51) Int. Cl. G02F 1/13357; G02F 1/1335; H01L 33/58

(52) U.S. Cl. 349/62; 438/30; 349/104; 257/E33.071

(57) ABSTRACT

According to one embodiment, a display device includes a main substrate, and a light control layer. The main substrate includes a main base having a main surface, a wavelength selective transmission layer provided on the main surface, and a circuit layer provided on the wavelength selective transmission layer. The light control layer is stacked with the main substrate and has variable optical characteristics. The wavelength selective transmission layer includes lower and upper reflecting layers, and first and second spacer layers. The upper reflecting layer is provided on the lower reflecting layer. The first spacer layer is provided between the lower and upper reflecting layers. The second spacer layer is provided between the lower and upper reflecting layers, and has a different thickness from the first spacer layer. The circuit layer includes first and second pixel electrodes, and first and second switching elements.

### CROSS-REFERENCE TO RELATED APPLICATIONS

This application is based upon and claims the benefit of priority from the prior Japanese Patent Application No. 2011-158477, filed on Jul. 19, 2011; the entire contents of which are incorporated herein by reference.

### FIELD

Embodiments described herein relate generally to a display device and a method for manufacturing the same.

### BACKGROUND

For example, in a display device, such as a liquid crystal display device in which a liquid crystal layer is provided between two substrates, blue, green, and red color filters are provided in a plurality of pixels to perform color display. When a color filter that absorbs light with a specific wavelength is used to obtain high color reproducibility, light use efficiency is reduced by the absorption of light by the color filter and a dark image is displayed.

In the display device, it is preferable to improve both light use efficiency and productivity.

### BRIEF DESCRIPTION OF THE DRAWINGS

FIG. 1 is a schematic cross-sectional view showing a display device according to a first embodiment;

FIG. 2 is a schematic enlarged cross-sectional view showing a part of the display device according to the first embodiment;

FIG. 3A to FIG. 3C are schematic cross-sectional views showing the display device according to the first embodiment;

FIG. 4A to FIG. 4C are schematic cross-sectional views showing another display device according to the first embodiment;

FIG. 5A and FIG. 5B are graphs showing the optical characteristics of materials;

FIG. 6A and FIG. 6B are graphs showing the characteristics of the display device according to the first embodiment;

FIG. 7A and FIG. 7B are graphs showing the characteristics of the display device according to the first embodiment;

FIG. 8 is a schematic view showing the operation of the display device according to the first embodiment;

FIG. 9 is a graph showing the characteristics of the display device according to the first embodiment;

FIG. 10A to FIG. 10C, FIG. 11A to FIG. 11C, and FIG. 12 are sequential schematic cross-sectional views showing a method for manufacturing the display device according to the first embodiment;

FIG. 13 is a schematic cross-sectional view showing another display device according to the first embodiment;

FIG. 14 is a schematic cross-sectional view showing another display device according to the first embodiment;

FIG. 15 is a schematic cross-sectional view showing another display device according to the first embodiment;

FIG. 16 is a schematic cross-sectional view showing a display device according to a second embodiment; and

FIG. 17A to FIG. 17C and FIG. 18A and FIG. 18B are sequential schematic cross-sectional views showing a method for manufacturing the display device according to the second embodiment.

### DETAILED DESCRIPTION

According to one embodiment, a display device includes a main substrate, and a light control layer. The main substrate includes a main base having a main surface, a wavelength selective transmission layer provided on the main surface, and a circuit layer provided on the wavelength selective transmission layer. The light control layer is stacked with the main substrate and has variable optical characteristics. The wavelength selective transmission layer includes a lower reflecting layer, an upper reflecting layer, a first spacer layer, and a second spacer layer. The upper reflecting layer is provided on the lower reflecting layer. The first spacer layer is provided between the lower reflecting layer and the upper reflecting layer. The second spacer layer is provided between the lower reflecting layer and the upper reflecting layer so as to be juxtaposed to the first spacer layer parallel to the main surface and has a thickness different from a thickness of the first spacer layer. The circuit layer includes a first pixel electrode, a second pixel electrode, a first switching element, and a second switching element. The first pixel electrode includes a portion overlapping the first spacer layer, as viewed along a first direction perpendicular to the main surface. The second pixel electrode includes a portion overlapping the second spacer layer, as viewed along the first direction. The first switching element is connected to the first pixel electrode. The second switching element is connected to the second pixel electrode.

According to another embodiment, a method is disclosed for manufacturing a display device. The device includes a main substrate including a main base having a main surface, a wavelength selective transmission layer provided on the main surface, and a circuit layer provided on the wavelength selective transmission layer. The wavelength selective absorption layer is stacked with the main substrate, and a light control layer is stacked with the wavelength selective absorption layer and has variable optical characteristics. The wavelength selective transmission layer includes a lower reflecting layer, an upper reflecting layer provided on the lower reflecting layer, a first spacer layer provided between the lower reflecting layer and the upper reflecting layer, and a second spacer layer provided between the lower reflecting layer and the upper reflecting layer so as to be juxtaposed to the first spacer layer in a first plane parallel to the main surface and has a thickness different from a thickness of the first spacer layer. The circuit layer includes a first pixel electrode including a portion overlapping the first spacer layer, as viewed along a first direction perpendicular to the main surface, a second pixel electrode including a portion overlapping the second spacer layer, as viewed along the first direction, a first switching element connected to the first pixel electrode, and a second switching element connected to the second pixel electrode. The wavelength selective absorption layer includes a first absorption layer provided on the first pixel electrode and a second absorption layer provided on the second pixel electrode and has an absorption spectrum different from an absorption spectrum of the first absorption layer. The method can include forming a lower reflecting film serving as the lower reflecting layer on the main surface of the main base. The method can include forming a first intermediate layer serving as a part of the first spacer layer on the lower reflecting film. The method can include forming a first mask member covering a first region of the first intermediate layer. The method can include removing a portion of the first intermediate layer not covered with the first mask member and reducing a thickness of a portion of the lower reflecting film not covered with the first mask member using over-etching. The method can include forming a second intermediate layer serving as another portion of the first spacer layer and at least a portion of the second spacer layer on the remaining first intermediate layer and the lower reflecting film after removing the first mask member. In addition, the method can include forming the upper reflecting layer on the second intermediate layer, and forming the circuit layer on the upper reflecting layer.

Various embodiments will be described hereinafter with reference to the accompanying drawings.

The drawings are illustrative or conceptual. In the drawings, for example, the scales of components are not necessarily equal to the actual scales. In addition, the same component may have different dimensions and scales in the drawings.

In the specification and the drawings, the same components are denoted by the same reference numerals and the detailed description thereof will not be repeated.

### First Embodiment

Next, a liquid crystal display device using liquid crystal will be described as an example of a display device according to a first embodiment.

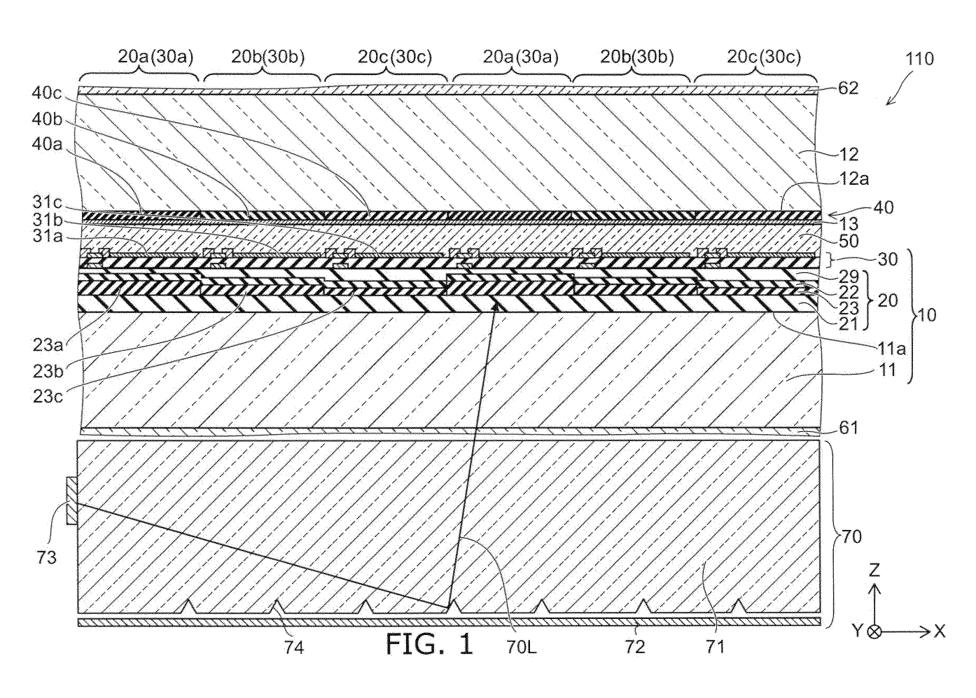

FIG. 1 is a schematic cross-sectional view illustrating the configuration of the display device according to the first embodiment.

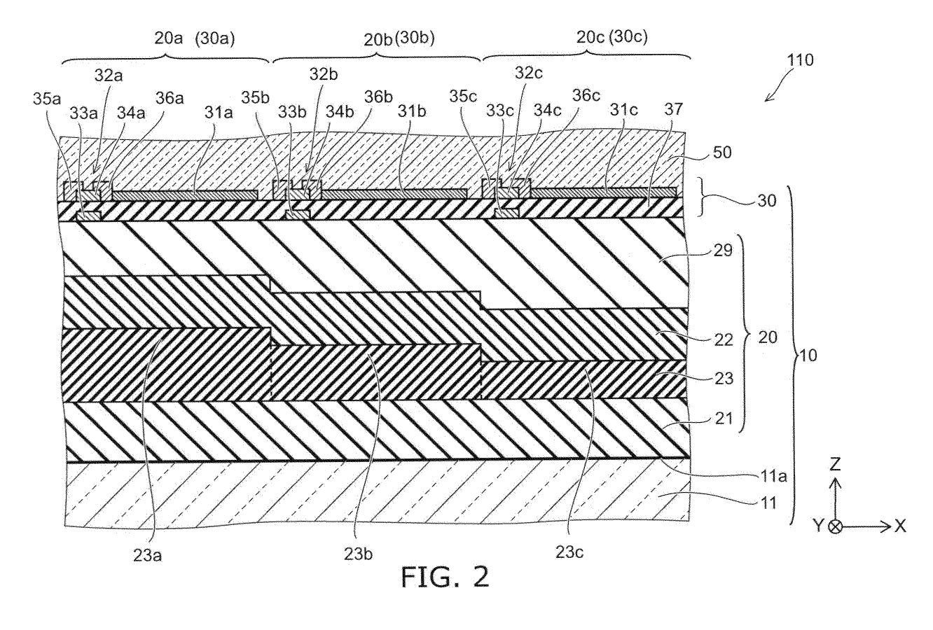

FIG. 2 is a schematic enlarged cross-sectional view illustrating a part of the configuration of the display device according to the first embodiment.

As shown in FIG. 1 and FIG. 2, a display device 110 according to the embodiment includes a main substrate 10 and a light control layer 50.

The light control layer 50 and the main substrate 10 are stacked. The optical characteristics of the light control layer 50 are variable. For example, a liquid crystal layer is used as the light control layer 50. The display device 110 may further include a wavelength selective absorption layer 40. The wavelength selective absorption layer 40 and the main substrate 10 are stacked.

In the specification, a stacked state includes a state in which two components directly overlap each other and a state in which two components overlap each other with another component interposed therebetween.

The main substrate 10 includes a main base 11, a wavelength selective transmission layer 20, and a circuit layer 30. The main base 11 includes a main surface 11a. The main base 11 is made of, for example, glass or resin. The main base 11 is, for example, light-transmissive.

The wavelength selective transmission layer 20 is provided on the main surface 11a. The circuit layer 30 is provided on the wavelength selective transmission layer 20. That is, the wavelength selective transmission layer 20 is provided between the main base 11 and the circuit layer 30.

A direction perpendicular to the main surface 11a is referred to as the Z-axis direction (first direction). An axis perpendicular to the Z-axis direction is referred to as the X-axis direction (second direction). An axis perpendicular to the Z-axis direction and the X-axis direction is referred to as the Y-axis direction.

The wavelength selective transmission layer 20 includes a lower reflecting layer 21, an upper reflecting layer 22, and an intermediate layer 23. The upper reflecting layer 22 is provided above the lower reflecting layer 21. The intermediate layer 23 is provided between the lower reflecting layer 21 and the upper reflecting layer 22.

In the specification, a state in which a component is provided above another component includes a state in which a component is provided on another component and a state in which a component is provided above another component with the third component interposed therebetween.

The wavelength selective transmission layer 20 includes a plurality of regions (for example, a first region 20a and a second region 20b). In this example, the wavelength selective transmission layer 20 includes the first region 20a, the second region 20b, and a third region 20c. A plurality of first regions 20a, second regions 20b, and third regions 20c are arranged in the X-Y plane. The intermediate layer 23 includes a plurality of layers corresponding to the plurality of regions. For example, the intermediate layer 23 includes a first spacer layer 23a and a second spacer layer 23b. The intermediate layer 23 may further include a third spacer layer 23c.

That is, the wavelength selective transmission layer 20 may include the first spacer layer 23a and the second spacer layer 23b. The first spacer layer 23a is provided between the lower reflecting layer 21 and the upper reflecting layer 22. The second spacer layer 23b is provided between the lower reflecting layer 21 and the upper reflecting layer 22. The second spacer layer 23b is provided to be juxtaposed with the first spacer layer 23a in a first plane (X-Y plane) parallel to the main surface 11a. The second spacer layer 23b and the first spacer layer 23a have different thicknesses.

A region including the lower reflecting layer 21, the first spacer layer 23a, and the upper reflecting layer 22 in the wavelength selective transmission layer 20 is the first region 20a. A region including the lower reflecting layer 21, the second spacer layer 23b, and the upper reflecting layer 22 in the wavelength selective transmission layer 20 is the second region 20b.

In the specific example, the wavelength selective transmission layer 20 further includes the third spacer layer 23c. The third spacer layer 23c is provided between the lower reflecting layer 21 and upper reflecting layer 22 and is juxtaposed with the first spacer layer 23a (and the second spacer layer 23b) in the X-Y plane. The thickness of the third spacer layer 23c is different from those of the first spacer layer 23a and the second spacer layer 23b.

For example, a region including the lower reflecting layer 21, the third spacer layer 23c, and the upper reflecting layer 22 in the wavelength selective transmission layer 20 is the third region 20c.

The lower reflecting layer 21 and the upper reflecting layer 22 reflect and transmit visible light. The first region 20a serves as a first color interference filter, which will be described below. The second region 20b serves as a second color interference filter. The third region 20c serves as a third color interference filter. That is, in this example, three color regions are provided.

However, the embodiment is not limited thereto. For example, the third region 20c may not be provided and two color regions may be provided. In addition, a fourth region may be further provided and four color regions may be provided. As such, in the embodiment, any kind of color may be used.

When the third region 20c is provided, the third spacer layer 23c may not be provided according to the configuration of the lower reflecting layer 21 and the upper reflecting layer 22. In this case, in the third region 20c, the lower reflecting layer 21 comes into contact with the upper reflecting layer 22. That is, the wavelength selective transmission layer 20 may include a region (third region 20c) which is provided between the lower reflecting layer 21 and the upper reflecting layer 22 and is juxtaposed with the region (first region 20a) in which the first spacer layer is provided and the region (second region 20b) in which the second spacer layer is provided in the X-Y plane.

The wavelength selective transmission layer 20 may include an interlayer film 29. The interlayer film 29 is provided between the upper reflecting layer 22 and the circuit layer 30. The interlayer film 29 planarizes, for example, the upper surface of the upper reflecting layer 22. For example, the interlayer film 29 may be made of at least one of the materials forming the lower reflecting layer 21, the intermediate layer 23, and the upper reflecting layer 22. The interlayer film 29 is provided, if needed, and may not be provided. An example of the configuration of the wavelength selective transmission layer 20 will be described below.

The circuit layer 30 includes a plurality of pixel regions (for example, a first pixel region 30a and a second pixel region 30b). In this example, the circuit layer 30 includes the first pixel region 30a, the second pixel region 30b, and a third pixel region 30c. The first pixel region 30a, the second pixel region 30b, and the third pixel region 30c correspond to the first region 20a, the second region 20b, and the third region 20c, respectively.

As shown in FIG. 2, a pixel electrode and a switching element are provided in each of the plurality of pixel regions.

Specifically, the circuit layer 30 includes a first pixel electrode 31a, a second pixel electrode 31b, a first switching element 32a, and a second switching element 32b.

The first pixel electrode 31a includes a portion which overlaps the first spacer layer 23a, as viewed from the Z-axis direction. The second pixel electrode 31b includes a portion which overlaps the second spacer layer 23b, as viewed from the Z-axis direction. The first switching element 32a is connected to the first pixel electrode 31a. The second switching element 32b is connected to the second pixel electrode 31b.

In this example, the circuit layer 30 further includes a third pixel electrode 31c and a third switching element 32c. The third pixel electrode 31c includes a portion which overlaps the third spacer layer 23c, as viewed from the Z-axis direction. That is, the third pixel electrode 31c includes a portion which overlaps the region (third region 20c) and is juxtaposed with to the first region 20a and the second region 20b, as viewed from the Z-axis direction. The third switching element 32c is connected to the third pixel electrode 31c.

For example, transistors (for example, thin film transistors) are used as the first to third switching elements 32a to 32c.

Specifically, the first switching element 32a includes a first gate 33a, a first semiconductor layer 34a, a first signal-line-side end 35a, and a first pixel-side end 36a. The second switching element 32b includes a second gate 33b, a second semiconductor layer 34b, a second signal-line-side end 35b, and a second pixel-side end 36b. The third switching element 32c includes a third gate 33c, a third semiconductor layer 34c, a third signal-line-side end 35c, and a third pixel-side end 36c.

The first to third gates 33a to 33c are connected to, for example, a scanning line (not illustrated). The first to third signal-line-side ends 35a to 35c are connected to, for example, a plurality of signal lines (not illustrated). A gate insulating film 37 is provided between the first gate 33a and the first semiconductor layer 34a, between the second gate 33b and the second semiconductor layer 34b, and between the third gate 33c and the third semiconductor layer 34c.

The first to third semiconductor layers 34a to 34c are made of a semiconductor, such as amorphous silicon or polysilicon.

The first signal-line-side end 35a is one of the source and the drain of the first switching element 32a. The first pixel-side end 36a is the other one of the source and the drain of the first switching element 32a. The second signal-line-side end 35b is one of the source and the drain of the second switching element 32b. The second pixel-side end 36b is the other one of the source and the drain of the second switching element 32b. The third signal-line-side end 35c is one of the source and the drain of the third switching element 32c. The third pixel-side end 36c is the other one of the source and the drain of the third switching element 32c.

The first to third pixel-side ends 36a to 36c are electrically connected to the first pixel electrodes 31a to 31c, respectively.

The circuit layer 30 may further include an auxiliary capacitance line (not illustrated). The circuit layer 30 may further include a control circuit which controls the operation of the switching element.

The wavelength selective transmission layer 20 is, for example, an insulating layer, which will be described below. The wavelength selective transmission layer 20 suppresses the diffusion of impurities from, for example, the main base 11 to the circuit layer 30. The wavelength selective transmission layer 20 planarizes, for example, the surface of the main base 11. The wavelength selective transmission layer 20 is used as an underlayer which is provided between the main base 11 and the circuit layer 30.

As illustrated in FIG. 1, in this example, a counter substrate 12 is provided so as to be opposite to the main surface 11a of the main base 11. The wavelength selective absorption layer 40 is provided on a counter main surface 12a (a surface opposite to the main surface 11a) of the counter substrate 12.

The wavelength selective absorption layer 40 includes a first absorption layer 40a and a second absorption layer 40b. In this example, the wavelength selective absorption layer 40 further includes a third absorption layer 40c.

The first absorption layer 40a includes a portion which overlaps the first spacer layer 23a, as viewed from the Z-axis direction. The first absorption layer 40a includes, for example, a portion which overlaps the first pixel electrode 31a, as viewed from the Z-axis direction.

The second absorption layer 40b includes a portion which overlaps the second spacer layer 23b, as viewed from the Z-axis direction. The second absorption layer 40b includes, for example, a portion which overlaps the second pixel electrode 31b, as viewed from the Z-axis direction. The second absorption layer 40b and the first absorption layer 40a have different absorption spectrums.

The third absorption layer 40c includes a portion which overlaps the region (third region 20c) and is juxtaposed with the first region 20a and the second region 20b, as viewed from the Z-axis direction. The third absorption layer 40c includes, for example, a portion which overlaps the third spacer layer 23c, as viewed from the Z-axis direction. The third absorption layer 40c includes, for example, a portion which overlaps the third pixel electrode 31c, as viewed from the Z-axis direction. The third absorption layer 40c has an absorption spectrum different from those of the first absorption layer 40a and the second absorption layer 40b.

For example, the first absorption layer 40a is a green absorption filter, the second absorption layer 40b is a blue absorption filter, and the third absorption layer 40c is a red absorption filter. The embodiment is not limited thereto, but the first to third absorption layers 40a to 40c may have any color relation (absorption wavelength) therebetween.

In this example, the light control layer 50 is provided between the wavelength selective absorption layer 40 and the main substrate 10. The light control layer 50 is disposed between the circuit layer 30 and the wavelength selective absorption layer 40. A counter electrode 13 is provided between the wavelength selective absorption layer 40 and the light control layer 50. The counter electrode 13 is provided on the wavelength selective absorption layer 40 which is formed on the counter main surface 12a of the counter substrate 12. The wavelength selective absorption layer 40 may be provided on the main substrate 10. The wavelength selective absorption layer 40 may be provided between the pixel electrode (for example, the first pixel electrode 31) and the wavelength selective transmission layer 20.

For example, a desired charge is supplied to each pixel electrode through the switching element. A voltage is applied between each pixel electrode and the counter electrode 13 and the voltage (for example, the electric field) is applied to the light control layer 50. The optical characteristics of the light control layer 50 are changed depending on the applied voltage (for example, the electric field) and the transmittance of each pixel is changed. In this way, display is performed.

When a liquid crystal layer is used as the light control layer 50, the orientation of the liquid crystal in the liquid crystal layer is changed depending on the applied voltage (for example, the electric field). When the orientation is changed, the optical characteristics (including at least one of birefringence, optical rotation properties, scattering properties, diffraction properties, and absorption properties) of the liquid crystal layer are changed.

As shown in FIG. 1, in this example, a first polarizing layer 61 and a second polarizing layer 62 are further provided. The main substrate 10, the wavelength selective absorption layer 40, and the light control layer 50 are arranged between the first polarizing layer 61 and the second polarizing layer 62. In this way, a change in the optical characteristics of the light control layer 50 (liquid crystal layer) is converted into a change in light transmittance and display is performed. The position of the polarizing layer is not limited to the above. The counter electrode 13 may be provided on the main substrate 10. In this case, for example, the electric field having a component parallel to the X-Y plane is applied to the light control layer 50 and the optical characteristics of the light control layer 50 is changed.

As shown in FIG. 1, the display device 110 according to the embodiment further includes an illuminating unit 70. The illuminating unit 70 emits illumination light 70L so as to be incident on the wavelength selective transmission layer 20 in a direction from the wavelength selective transmission layer 20 to the wavelength selective absorption layer 40.

The illuminating unit 70 includes, for example, a light source 73, a light guide body 71, a reflecting film 72 for illumination, and a traveling direction change portion 74. The light source 73 generates light. For example, a semiconductor light emitting element (for example, an LED) is used as the light source 73. The light source 73 is arranged, for example, on the side of the light guide body. The light guide body 71 is arranged between the reflecting film 72 for illumination and the main substrate 10. Light generated by the light source 73 is incident on the light guide body 71. For example, light is propagated in the light guide body 71 while being totally reflected. The traveling direction change portion 74 changes the traveling direction of light propagated in the light guide body 71 such that light is incident on the main substrate 10 with high efficiency. For example, a structure with an uneven shape, such as a groove, is used as the traveling direction change portion 74. For example, a part of the light whose traveling direction is changed by the traveling direction change portion 74 travels to the main substrate 10. Light emitted from the light source 73 of the illuminating unit 70 may be propagated in the main base 11 and the propagated light may be incident on the wavelength selective transmission layer 20.

The wavelength selective transmission layer 20 transmits light with a specific wavelength and reflects light with wavelengths other than the specific wavelength. The wavelength selective transmission layer 20 is, for example, a Farbry-Pelot interference filter. When the wavelength selective transmission layer 20 with the above-mentioned optical characteristics is used as the underlayer of the circuit layer 30, it is possible to obtain good optical characteristics (high light use efficiency which will be described below) while stably operating the circuit layer 30. The wavelength selective transmission layer 20 is manufactured at the same time (or continuously with) when the underlayer is manufactured. The underlayer is manufactured before the circuit layer 30 is manufactured. Therefore, productivity is high. In this way, it is possible to provide a display device with high light use efficiency and high productivity.

Next, an example of the wavelength selective transmission layer 20 will be described.

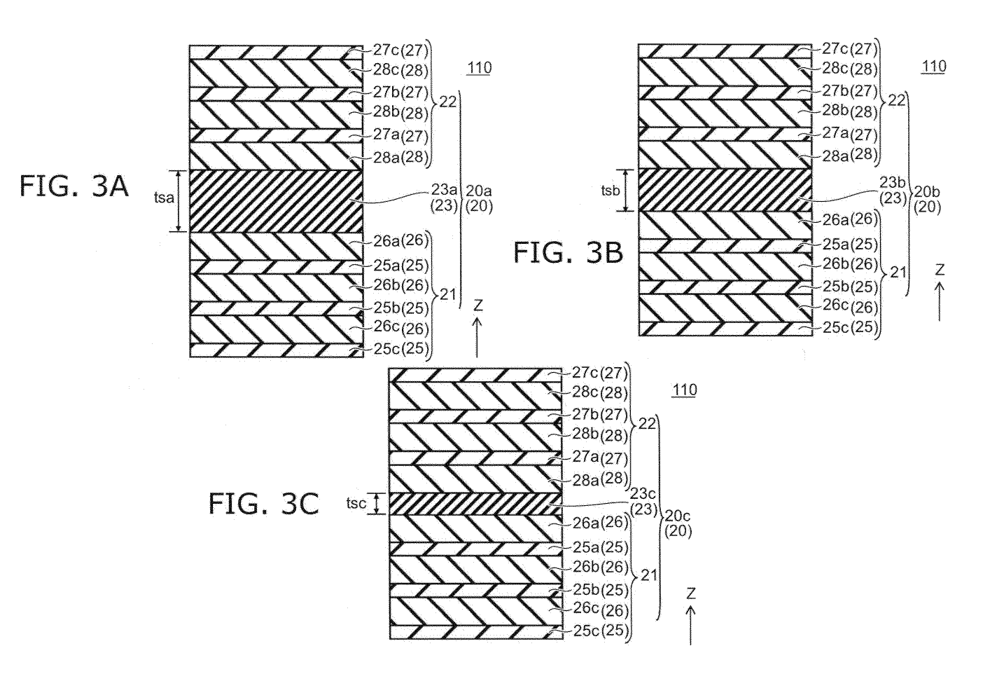

FIG. 3A to FIG. 3C are schematic cross-sectional views illustrating the configuration of the display device according to the first embodiment.

FIG. 3A to FIG. 3C illustrate the configuration of the wavelength selective transmission layer 20 in the first region 20a, the second region 20b, and the third region 20c, respectively. In FIG. 3A to FIG. 3C, the interlayer film 29 is omitted.

As shown in FIG. 3A to FIG. 3C, the lower reflecting layer 21 may include a first dielectric film 25 and a second dielectric film 26. The second dielectric film 26 and the first dielectric film 25 are stacked in the Z-axis direction. The second dielectric film 26 and the first dielectric film 25 have different refractive indexes.

In this example, a plurality of first dielectric films 25 are provided and a plurality of second dielectric films 26 are provided. The plurality of first dielectric films 25 and the plurality of second dielectric films 26 are alternately stacked in the Z-axis direction.

The upper reflecting layer 22 may include a third dielectric film 27 and a fourth dielectric film 28. The fourth dielectric film 28 and the third dielectric film 27 are stacked in the Z-axis direction. The fourth dielectric film 28 and the third dielectric film 27 have different refractive indexes.

In this example, a plurality of third dielectric films 27 are provided and a plurality of fourth dielectric films 28 are provided. The plurality of third dielectric films 27 and the plurality of fourth dielectric films 28 are alternately stacked in the Z-axis direction.

For example, a second dielectric film 26a, which is one of the second dielectric films 26, comes into contact with the intermediate layer 23. For example, a fourth dielectric film 28a, which is one of the fourth dielectric films 28, comes into contact with the intermediate layer 23.

For example, in the lower reflecting layer 21, a first dielectric film 25c, a second dielectric film 26c, a first dielectric film 25b, a second dielectric film 26b, a first dielectric film 25a, and the second dielectric film 26a are stacked in this order.

For example, in the upper reflecting layer 22, the fourth dielectric film 28a, a third dielectric film 27a, a fourth dielectric film 28b, a third dielectric film 27b, a fourth dielectric film 28c, and a third dielectric film 27c are stacked in this order.

As shown in FIG. 3A to FIG. 3C, in each of the first region 20a, the second region 20b, and the third region 20c, the first spacer layer 23a, the second spacer layer 23b, and the third spacer layer 23c are provided between the lower reflecting layer 21 and the upper reflecting layer 22.

The thickness tsb of the second spacer layer 23b is different from the thickness tsa of the first spacer layer 23a.

The thickness tsc of the third spacer layer 23c is different from the thickness tsa of the first spacer layer 23a and is also different from the thickness tsb of the second spacer layer 23b. The thickness tsc may be zero.

The first dielectric film 25 (for example, the first dielectric films 25a to 25c) may be made of, for example, silicon nitride (SiNₓ). The second dielectric film 26 (for example, the second dielectric films 26a to 26c) may be made of, for example, silicon oxide (SiO₂). The intermediate layer 23 may be made of, for example, silicon nitride (SiNₓ). The third dielectric film 27 (for example, the third dielectric films 27a to 27c) may be made of, for example, silicon nitride (SiNₓ). The fourth dielectric film 28 (for example, the fourth dielectric films 28a to 28c) may be made of, for example, silicon oxide (SiO₂). The content of nitrogen in the first dielectric film 25 may be equal to or different from the content of nitrogen in the third dielectric film 27. The content of nitrogen in the intermediate layer 23 may be equal to or different from the content of nitrogen in the first dielectric film 25. The content of nitrogen in the intermediate layer 23 may be equal to or different from the content of nitrogen in the third dielectric film 27.

For example, the first dielectric film 25 and the second dielectric film 26 include at least one of silicon oxide, silicon nitride, and silicon oxynitride. The content of at least one of oxygen and nitrogen in the first dielectric film 25 is different from the content of at least one of oxygen and nitrogen in the second dielectric film 26. In this way, the second dielectric film 26 has a refractive index different from that of the first dielectric film 25.

Similarly, the third dielectric film 27 and the fourth dielectric film 28 include at least one of silicon oxide, silicon nitride, and silicon oxynitride. The content of at least one of oxygen and nitrogen in the third dielectric film 27 is different from the content of at least one of oxygen and nitrogen in the fourth dielectric film 28. In this way, the fourth dielectric film 28 has a refractive index different from that of the third dielectric film 27.

As described above, the intermediate layer 23 is made of a material different from that forming the uppermost layer (for example, the second dielectric film 26a) of the lower reflecting layer 21. In addition, the intermediate layer 23 is made of a material different from that forming the lowermost layer (for example, the fourth dielectric film 28a) of the upper reflecting layer 22. The refractive index of the intermediate layer 23 is different from that of the uppermost layer (for example, the second dielectric film 26a) of the lower reflecting layer 21. In addition, the refractive index of the intermediate layer 23 is different from that of the lowermost layer (for example, the fourth dielectric film 28a) of the upper reflecting layer 22.

That is, in the embodiment, one of the first dielectric film 25 and the second dielectric film 26 comes into contact with the first spacer layer 23a and the second spacer layer 23b. For example, the refractive index of the one of the first dielectric film 25 and the second dielectric film 26 is less than the refractive index of the first spacer layer 23a and is less than the refractive index of the second spacer layer 23b. Similarly, one of the third dielectric film 27 and the fourth dielectric film 28 comes into contact with the first spacer layer 23a and the second spacer layer 23b. For example, the refractive index of the one of the third dielectric film 27 and the fourth dielectric film 28 is less than the refractive index of the first spacer layer 23a and is less than the refractive index of the second spacer layer 23b. The embodiment is not limited thereto, and the refractive indices are arbitrary.

In this way, in the first region 20a, light interference occurs between the lower reflecting layer 21 and the upper reflecting layer 22 (in the first spacer layer 23a). Then, light with a wavelength corresponding to the optical distance (for example, the thickness of the first spacer layer 23a) between the lower reflecting layer 21 and the upper reflecting layer 22 passes through the wavelength selective transmission layer 20 and light with the other wavelengths is reflected therefrom.

Similarly, in the second region 20b, for example, light with a wavelength corresponding to the thickness of the second spacer layer 23b passes through the wavelength selective transmission layer 20 and light with the other wavelengths is reflected therefrom. In the third region 20c, for example, light with a wavelength corresponding to the thickness of the third spacer layer 23c (the optical distance between the lower reflecting layer 21 and the upper reflecting layer 22) passes through the wavelength selective transmission layer 20 and light with the other wavelengths is reflected therefrom.

In this example, the number of first dielectric films 25 is three, the number of second dielectric films 26 is three, the number of third dielectric films 27 is three, and the number of fourth dielectric films 28 is three. However, the embodiment is not limited thereto. The number of films may be changed.

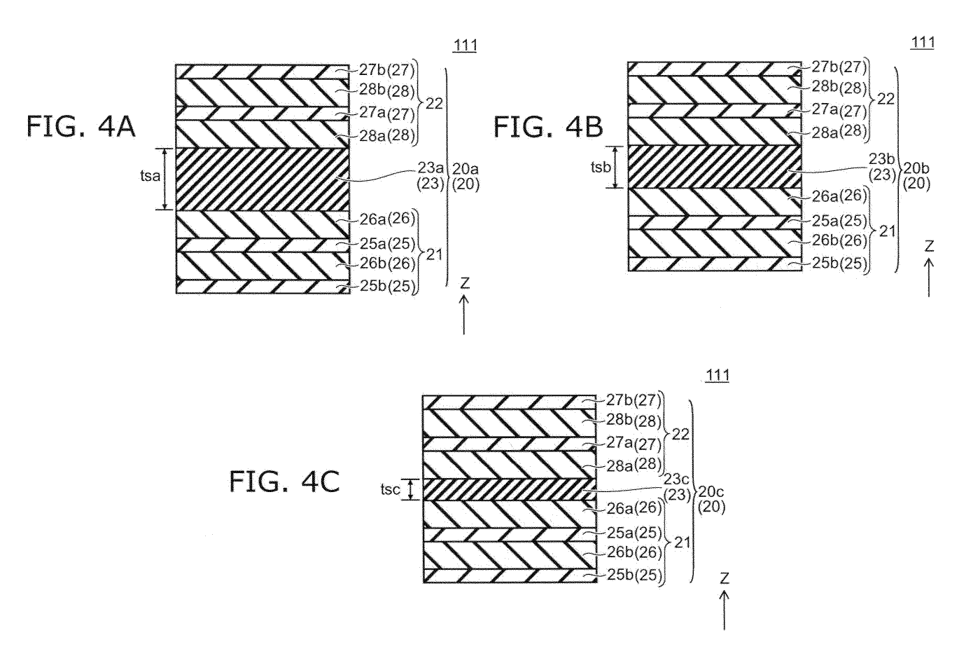

FIG. 4A to FIG. 4C are schematic cross-sectional views illustrating the configuration of another display device according to the first embodiment.

As shown in FIG. 4A to FIG. 4C, in another display device 111 according to the embodiment, the number of first dielectric films 25 is two, the number of second dielectric films 26 is two, the number of third dielectric films 27 is two, and the number of fourth dielectric films 28 is two.

In addition, the number of first dielectric films 25 and the number of second dielectric films 26 may be different from the number of third dielectric films 27 and the number of fourth dielectric films 28.

As such, the lower reflecting layer 21 and the upper reflecting layer 22 may have any configuration.

Next, an example of the characteristics of the wavelength selective transmission layer 20 will be described. That is, an example of the characteristic simulation result of the wavelength selective transmission layer 20 will be described. In the simulation, the model of the configuration of the display device 111 (the number of first dielectric films 25 is two, the number of second dielectric films 26 is two, the number of third dielectric films 27 is two, and the number of fourth dielectric films 28 is two) is used.

In this model, the first dielectric film 25, the third dielectric film 27, and the intermediate layer 23 are made of silicon nitride (SiN), and the second dielectric film 26 and the fourth dielectric film 28 are made of silicon oxide (SiO₂). The thickness of each of the first dielectric films 25a and 25b is 58 nanometers (nm). The thickness of each of the second dielectric films 26a and 26b is 92 nm. The thickness of each of the third dielectric films 27a and 27b is 58 nm. The thickness of each of the fourth dielectric films 28a and 28b is 92 nm. The thickness of the first spacer layer 23a is 115 nm. The thickness of the second spacer layer 23b is 78 nm. The thickness of the third spacer layer 23c is 30 nm.

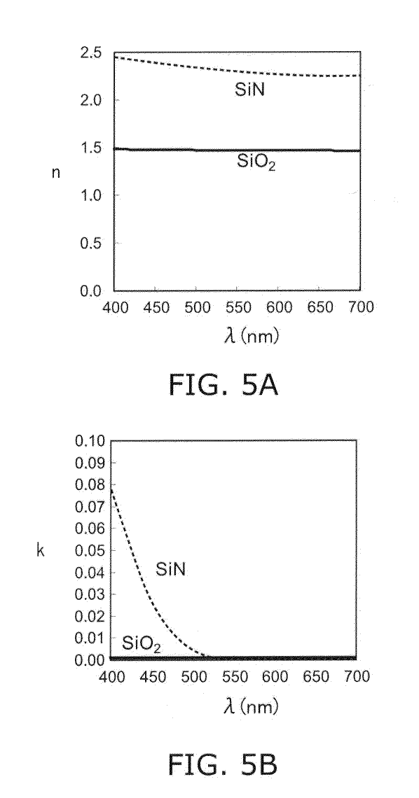

FIG. 5A and FIG. 5B are graphs illustrating the optical characteristics of materials.

FIG. 5A and FIG. 5B illustrate the optical characteristics of the materials used in the simulation. FIG. 5A illustrates a real part n of a complex refractive index and FIG. 5B illustrates an imaginary part k of the complex refractive index. In FIG. 5A and FIG. 5B, the horizontal axis indicates a wavelength λ.

As shown in FIG. 5A, for example, when the wavelength λ is 550 nm, the refractive index n of the silicon nitride film (SiN) is 2.3.

The optical characteristics shown in FIG. 5A and FIG. 5B are used to simulate the characteristics of the wavelength selective transmission layer 20.

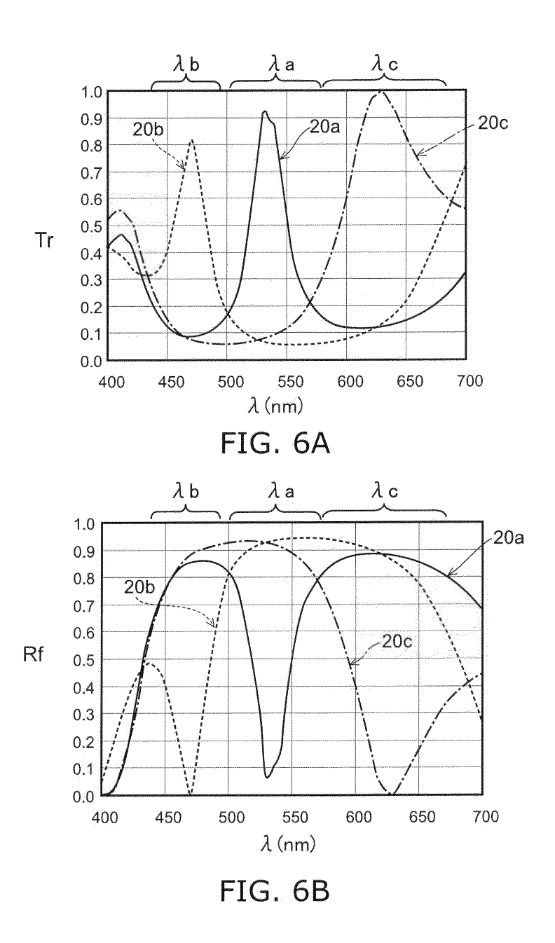

FIG. 6A and FIG. 6B are graphs illustrating the characteristics of the display device according to the first embodiment.

FIG. 6A and FIG. 6B illustrate the characteristics simulation result of the wavelength selective transmission layer 20. FIG. 6A illustrates a transmission spectrum and FIG. 6B illustrates a reflection spectrum. In FIG. 6A and FIG. 6B, the horizontal axis indicates the wavelength λ. In FIG. 6A, the vertical axis indicates transmittance Tr. In FIG. 6B, the vertical axis indicates reflectance Rf.

As shown in FIG. 6A and FIG. 6B, in the first region 20a, the transmittance Tr is high in the green wavelength band (first wavelength band λa) and the reflectance Rf is high in the wavelength bands other than green. In the second region 20b, the transmittance Tr is high in the blue wavelength band (second wavelength band λb) and the reflectance Rf is high in the wavelength bands other than blue. In the third region 20c, the transmittance Tr is high in the red wavelength band (third wavelength band λc) and the reflectance Rf is high in the wavelength bands other than red.

Since a portion of light is also absorbed by the wavelength selective transmission layer 20, the sum of the transmittance Tr and the reflectance Rf is not equal to 1, but is close to 1.

As such, in the first region 20a (a region of the wavelength selective transmission layer 20 including the lower reflecting layer 21, the first spacer layer 23a, and the upper reflecting layer 22), light in the first wavelength band λa is transmitted and components of visible light which are in the wavelength bands other than the first wavelength band λa are reflected.

In the second region 20b (a region of the wavelength selective transmission layer 20 including the lower reflecting layer 21, the second spacer layer 23b, and the upper reflecting layer 22), light in the second wavelength band λb different from the first wavelength band λa is transmitted and components of visible light which are in the wavelength bands other than the second wavelength band λb are reflected.

In the third region 20c (the region which is provided between the lower reflecting layer 21 and the upper reflecting layer 22, is juxtaposed with to the region in which the first spacer layer 23a is provided and the region in which the second spacer layer 23b is provided in the X-Y plane, and includes, for example, the third spacer layer 23c), light in the third wavelength band λc different from the first wavelength band λa and the second wavelength band λb is transmitted and components of visible light which are in the wavelength bands other than the third wavelength band λc are reflected.

As such, in one example of the embodiment, the first wavelength band λa includes the green wavelength band, the second wavelength band λb includes the blue wavelength band, and the third wavelength band λc includes the red wavelength band. The first wavelength band λa, the second wavelength band λb, and the third wavelength band λc may be interchanged.

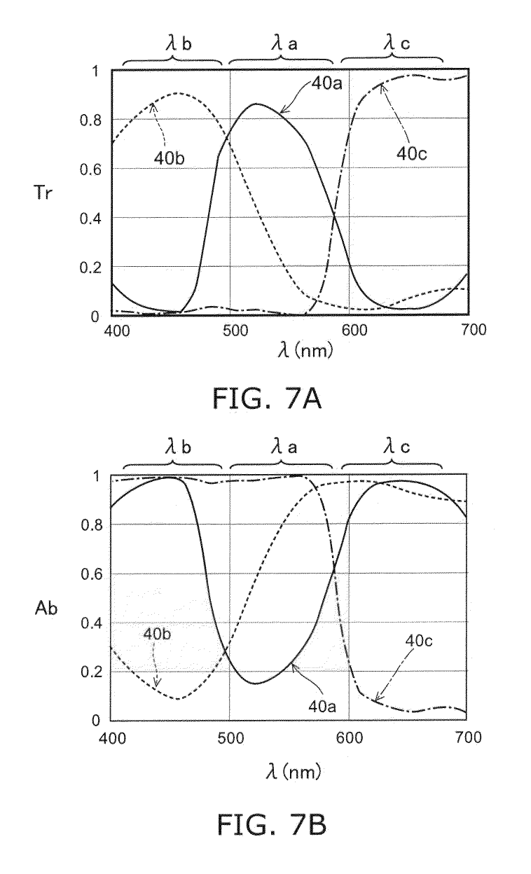

FIG. 7A and FIG. 7B are graphs illustrating an example of the characteristics of the display device according to the first embodiment.

FIG. 7A and FIG. 7B illustrate the characteristics of the wavelength selective absorption layer 40. FIG. 7A illustrates a transmission spectrum and FIG. 7B illustrates an absorption spectrum. In FIG. 7A and FIG. 7B, the horizontal axis indicates the wavelength λ. In FIG. 7A, the vertical axis indicates the transmittance Tr. In FIG. 7B, the vertical axis indicates absorptance λb.

As shown in FIG. 7A, in each of the first absorption layer 40a, the second absorption layer 40b, and the third absorption layer 40c, the transmittance Tr of light in the first wavelength band λa, the second wavelength band λb, and the third wavelength band λc is high. The first absorption layer 40a, the second absorption layer 40b, and the third absorption layer 40c are green, blue, and red absorption color filters, respectively.

As shown in FIG. 7B, the absorptance Ab of light in the first wavelength band λa by the first absorption layer 40a is less than the absorptance Ab of components of visible light in the wavelength bands other than the first wavelength band λa by the first absorption layer 40a. The absorptance Ab of light in the second wavelength band λb by the second absorption layer 40b is less than the absorptance Ab of components of visible light in the wavelength bands other than the second wavelength band λb by the second absorption layer 40b. The absorptance Ab of light in the third wavelength band λc by the third absorption layer 40c is less than the absorptance Ab of components of visible light in the wavelength bands other than the third wavelength band λc by the third absorption layer 40c.

The wavelength selective transmission layer 20 having the characteristics illustrated in FIG. 6A and FIG. 6B and the wavelength selective absorption layer 40 having the characteristics illustrated in FIG. 7A and FIG. 7B are stacked to improve light use efficiency.

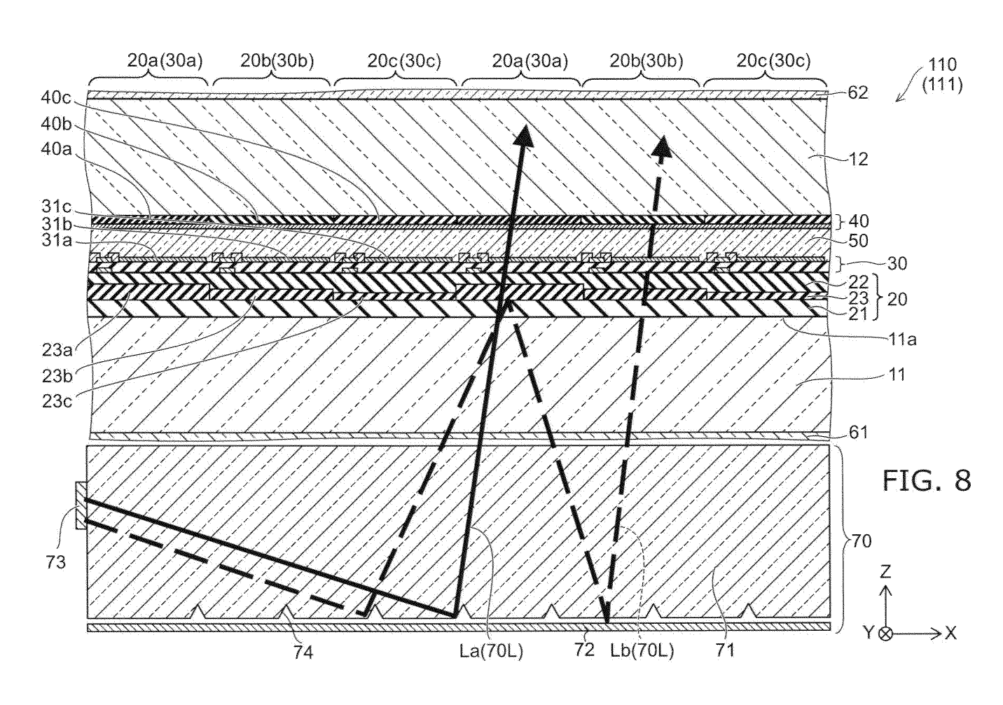

FIG. 8 is a schematic diagram illustrating the operation of the display device according to the first embodiment.

As shown in FIG. 8, the illuminating unit 70 emits the illumination light 70L so as to be incident on the wavelength selective transmission layer 20 in the direction from the wavelength selective transmission layer 20 to the wavelength selective absorption layer 40.

A first light component La in a first wavelength band λa in the illumination light 70L passes through the first region 20a of the wavelength selective transmission layer 20. The first light component La sequentially passes through the light control layer 50 and the first absorption layer 40a and is then emitted to the outside. The intensity of light emitted to the outside varies depending on the state of the light control layer 50.

A light component (for example, a second light component Lb) within the wavelength bands other than the first wavelength band λa in the illumination light 70L is reflected from the first region 20a of the wavelength selective transmission layer 20 and returns to the illuminating unit 70. The second light component Lb is reflected from, for example, the reflecting layer 72 for illumination in the illuminating unit 70 and is then incident on the wavelength selective transmission layer 20. Then, the second light component Lb passes through, for example, the second region 20b of the wavelength selective transmission layer 20. The second light component Lb sequentially passes through the light control layer 50 and the second absorption layer 40b and is then emitted to the outside. The intensity of light emitted to the outside varies depending on the state of the light control layer 50.

As such, the illumination light 70L emitted from the illuminating unit 70 is reflected from a portion (first region 20a) of the wavelength selective transmission layer 20 including the first spacer layer 23a and at least a portion of the reflected light (for example, the second light component Lb) is incident on a portion (second region 20b) of the wavelength selective transmission layer 20 including the second spacer layer 23b.

As such, in the display device 110 (or the display device 111), light which does not pass through a specific region of the wavelength selective transmission layer 20 returns to the illuminating unit 70 and is reused. Therefore, high light use efficiency is obtained. In this way, bright display is obtained. In addition, it is possible to reduce power consumption.

In this configuration, for example, 90% or more of the light returning to the illuminating unit 70 is reused. It is possible to obtain a reuse rate of 95% according to conditions.

Light reaching the wavelength selective absorption layer 40 passes through the wavelength selective transmission layer 20. Therefore, the wavelength characteristics of light are controlled so as to be suitable for the absorption characteristics of the wavelength selective absorption layer 40. The component of light absorbed by the wavelength selective absorption layer 40 is less than that when the wavelength selective transmission layer 20 is not used. Therefore, it is possible to reduce light loss. In addition, even when the absorptance Ab of the wavelength selective absorption layer 40 is low, it is possible to obtain desired color characteristics (for example, color reproducibility).

For example, the color gamut (area) of the wavelength selective transmission layer 20 is, for example, 30% of the color gamut (area) of NTSC. The color gamut (area) of the wavelength selective absorption layer 40 is about 55% of the color gamut (area) of NTSC. The color gamut (area) when the wavelength selective transmission layer 20 and the wavelength selective absorption layer 40 are stacked can be significantly more than that when the wavelength selective transmission layer 20 is not used and only the wavelength selective absorption layer 40 is used.

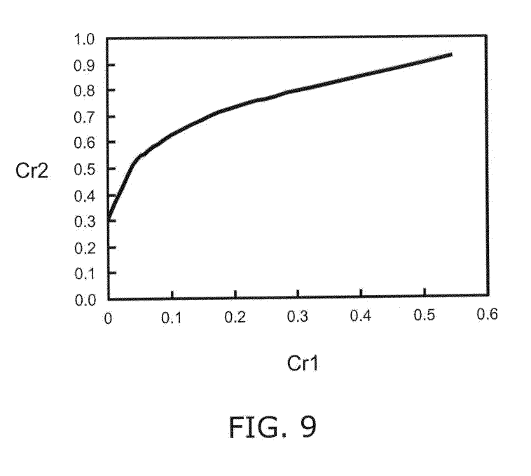

FIG. 9 is a graph illustrating the characteristics of the display device according to the first embodiment.

In FIG. 9, the horizontal axis indicates the ratio of the color gamut of the wavelength selective absorption layer 40 to the color gamut of NTSC (single NTSC ratio Cr1). For example, the single NTSC ratio Cr1 is changed by changing the thickness of the blue, green, and red absorption color filters which are used as the wavelength selective absorption layer 40. In FIG. 9, the vertical axis indicates the ratio of the color gamut when the wavelength selective absorption layer 40 and the wavelength selective transmission layer 20 are stacked to the color gamut of NTSC (total NTSC ratio Cr2).

As shown in FIG. 9, when the wavelength selective absorption layer 40 and the wavelength selective transmission layer 20 (NTSC ratio: 30%) are stacked, the total NTSC ratio Cr2 is 90% or more. In this case, the single NTSC ratio Cr1 of the wavelength selective absorption layer 40 is about 55%.

For example, when the single NTSC ratio Cr1 is about 17%, a total NTSC ratio Cr2 of about 70% can be obtained. Sufficient color reproducibility is obtained by this value.

When the single NTSC ratio Cr1 of the wavelength selective absorption layer 40 is set to a small value, it is possible to reduce the thickness of the wavelength selective absorption layer 40. In this way, it is possible to reduce light loss in the wavelength selective absorption layer 40. In other words, the use of the stacked structure of the wavelength selective transmission layer 20 and the wavelength selective absorption layer 40 makes it possible to obtain high color reproducibility even when the wavelength selective absorption layer 40 with low color purity is used. In this way, it is possible to improve light use efficiency.

In the embodiment, since the wavelength selective transmission layer 20 has the function of the underlayer which is provided as the base of the switching element, the generally used underlayer may not be provided, which results in high productivity.

There is a configuration in which an interference-type color filter is used as an absorption-type color filter. However, for example, when the interference-type color filter is provided on the counter substrate 12 which is opposite to the main substrate 10 having the switching element provided thereon, a process of manufacturing the interference-type color filter is added, which results in a significant reduction in productivity. Also in the case where the interference-type color filter is provided on the main substrate 10, when the color filter is disposed only in a pixel electrode portion, a process of manufacturing the interference-type color filter is also added since the underlayer is provided between the switching element and the main base 11. For example, it is necessary to introduce a new apparatus for manufacturing the interference-type color filter.

In contrast, in the display device 111 (or the display device 110) according to the embodiment, the film used as the underlayer functions as the wavelength selective transmission layer 20. Therefore, a process of forming the wavelength selective transmission layer 20 can be performed by the manufacturing apparatus used to form the underlayer and it is not necessary to introduce a new apparatus. As such, in the embodiment, it is possible to obtain high light emission efficiency while maintaining high productivity.

In particular, it is preferable that the wavelength selective transmission layer 20 include at least one of silicon oxide, silicon nitride, and silicon oxynitride. In this way, the wavelength selective transmission layer 20 has a high insulation performance. For example, the effect of preventing impurities from being diffused from the main base 11 to the circuit layer 30 is improved. In addition, for example, it is easy to improve the flatness of the surface of the main base 11. The use of these materials makes it possible to form the wavelength selective transmission layer 20 using, for example, a chemical vapor deposition (CVD) method and stably obtain uniform characteristics. In addition, conditions, such as gas introduced into a processing chamber during the formation of the layer by the CVD method, can be changed to form a plurality of films included in the wavelength selective transmission layer 20 with high controllability and efficiency.

Next, an example of a method of manufacturing the display device 111 according to the embodiment will be described. The following method can also be applied to the display device 110 by changing the number of times the dielectric film is formed.

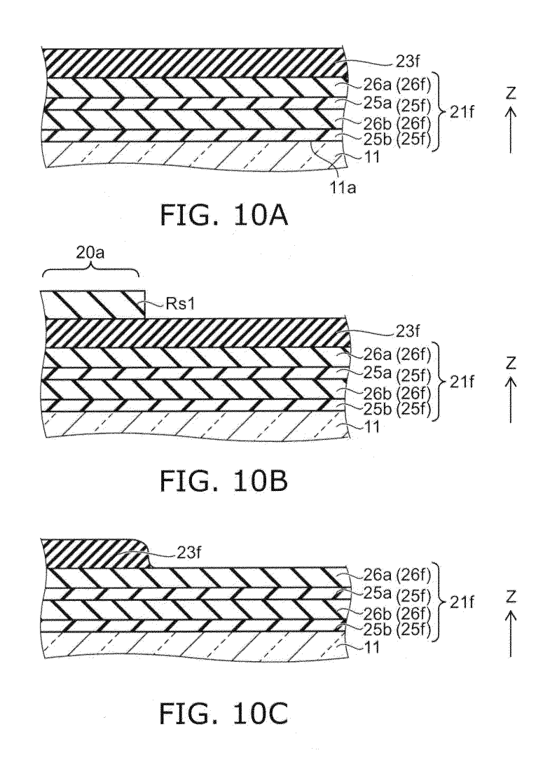

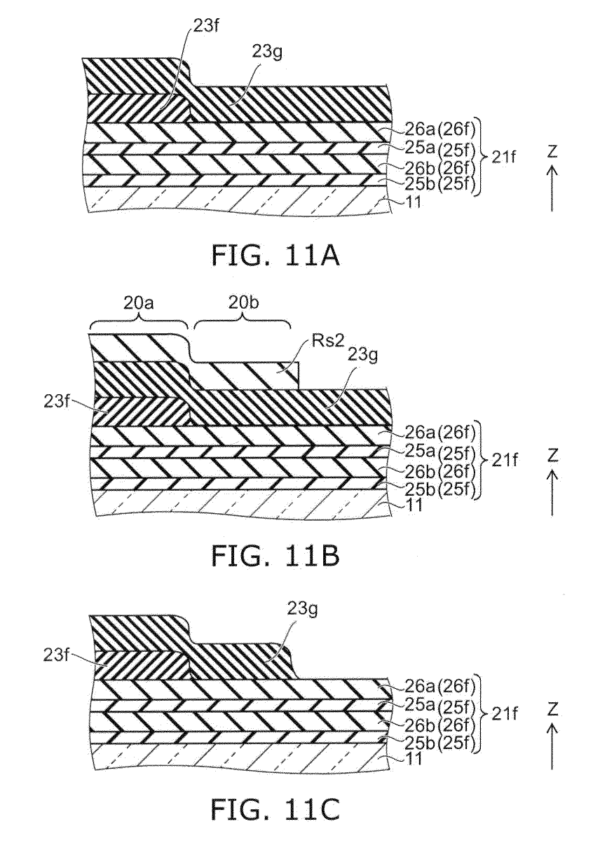

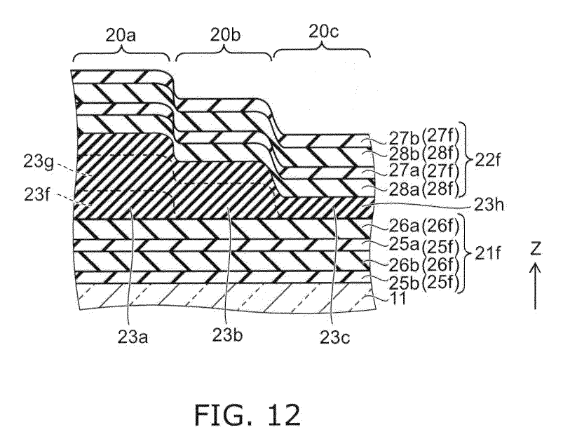

FIG. 10A to FIG. 10C, FIG. 11A to FIG. 11C, and FIG. 12 are schematic cross-sectional views illustrating the processes of the method of manufacturing the display device according to the first embodiment.

As shown in FIG. 10A, a lower reflecting film 21f which will be the lower reflecting layer 21 is formed on the main surface 11a of the main base 11. For example, a glass substrate is used as the main base 11.

Specifically, silicon nitride films 25f which will be the first dielectric films 25 and silicon oxide films 26f which will be the second dielectric films 26 are alternately formed on the main surface 11a of the main base 11. These films are formed by, for example, a CVD method. The flow rate of gas used can be controlled to continuously form these films.

A first intermediate layer 23f which will be a portion of the intermediate layer 23 (for example, a portion of the first spacer layer 23a) is formed on the lower reflecting film 21f. In this example, a silicon nitride film is formed as the first intermediate layer 23f by the CVD method.

As shown in FIG. 10B, a first mask member Rs1 covering the first region 20a of the first intermediate layer 23f is formed.

As shown in FIG. 10C, a portion of the first intermediate layer 23f which is not covered with the first mask member Rs1 is removed. The removal process is performed by, for example, a chemical dry etching (CDE) method. In this case, over-etching may be performed, if necessary. In this way, an unnecessary portion of the first intermediate layer 23f can be sufficiently removed. The thickness of the portion of the lower reflecting film 21f which is not covered with the first mask member Rs1 may be reduced. Then, the first mask member Rs1 is removed.

As shown in FIG. 11A, after the first mask member Rs1 is removed, a second intermediate layer 23g which will be another portion of the first spacer layer 23a and will be at least a portion of the second spacer layer 23b is formed on the remaining first intermediate layer 23f and the lower reflecting film 21f. In this example, a silicon nitride film is formed as the second intermediate layer 23g by the CVD method.

As shown in FIG. 11B, a second mask member Rs2 is formed so as to cover the first region 20a and the second region 20b different from the first region 20a of the second intermediate layer 23g.

As shown in FIG. 11C, a portion of the second intermediate layer 23g which is not covered with the second mask member Rs2 is removed. In the removal process, for example, when the CDE method is used, over-etching may be performed if necessary. In this way, it is possible to sufficiently remove an unnecessary portion of the second intermediate layer 23g. The thickness of the portion of the lower reflecting film 21f which is not covered with the second mask member Rs2 may be removed. Then, the second mask member Rs2 is removed.

As shown in FIG. 12, after the second mask member Rs2 is removed, a third intermediate layer 23h which will be another portion of the first spacer layer 23a and a portion of the second spacer layer 23b is formed on the remaining second intermediate layer 23g and the lower reflecting film 21f. In this example, a silicon nitride film is formed as the third intermediate layer 23h by the CVD method.

The upper reflecting layer 22 is formed on the second intermediate layer 23g (on the third intermediate layer 23h in this example). Specifically, silicon oxide films 28f which will be the fourth dielectric films 28 and silicon nitride films 27f which will be the third dielectric films 27 are alternately formed. These films are formed by, for example, the CVD method.

In addition, if necessary, the interlayer film 29 is formed on the upper reflecting layer 22. In this way, the wavelength selective transmission layer 20 is formed. Then, the circuit layer 30 is formed on the wavelength selective transmission layer 20 (for example, on the upper reflecting layer 22). Then, the display device 111 is formed through a predetermined process.

In the above, the thickness of the first intermediate layer 23f is, for example, 37 nm. The thickness of the second intermediate layer 23g is, for example, 48 nm. The thickness of the third intermediate layer 23h is, for example, 30 nm. In this way, the thickness of the intermediate layer 23 (that is, the first spacer layer 23a) in the first region 20a is 115 nm. The thickness of the intermediate layer 23 (that is, the second spacer layer 23b) in the second region 20b is 78 nm. The thickness of the intermediate layer 23 (that is, the third spacer layer 23c) in the third region 20c is 30 nm.

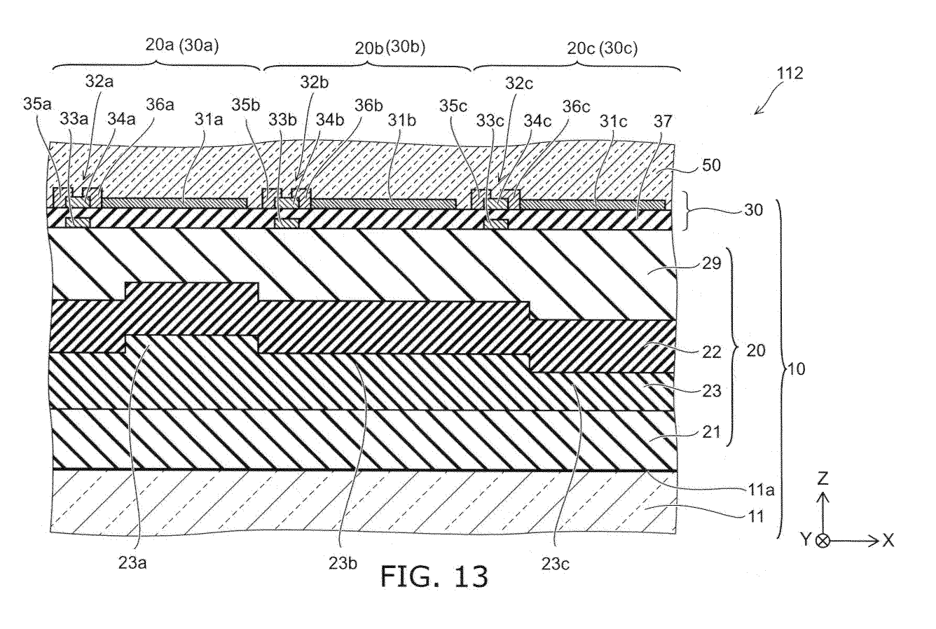

FIG. 13 is a schematic cross-sectional view illustrating the configuration of another display device according to the first embodiment. As shown in FIG. 13, in another display device 112 according to the embodiment, the intermediate layer 23 with a thickness equal to that of the second spacer layer 23b is provided in the wavelength selective transmission layer 20 between the first switching element 32a and the main base 11. The first spacer layer 23a is provided in the wavelength selective transmission layer 20 between the first pixel electrode 31a and the main base 11.

The second spacer layer 23b is provided in the wavelength selective transmission layer 20 between the second switching element 32b and the main base 11. The second spacer layer 23b is provided in the wavelength selective transmission layer 20 between the second pixel electrode 31b and the main base 11.

The intermediate layer 23 with a thickness equal to that of the second spacer layer 23b is provided in the wavelength selective transmission layer 20 between the third switching element 32c and the main base 11. The third spacer layer 23c is provided in the wavelength selective transmission layer 20 between the third pixel electrode 31c and the main base 11.

As such, in one pixel region, the thickness of the intermediate layer 23 may be changed. The characteristics of the wavelength selective transmission layer 20 between each switching element and the main base 11 may be designed in order to improve the function of, for example, the underlayer. For example, the wavelength selective transmission layer 20 between each switching element and the main base 11 is designed such that the effect of preventing the diffusion of impurities is improved. In addition, the wavelength selective transmission layer 20 is designed such that the effect of preventing the occurrence of, for example, a leakage current (for example, an optical leakage current) from the switching element is improved. Furthermore, the wavelength selective transmission layer 20 is designed such that the flatness of the surface is uniform. In this way, for example, it is possible to prevent the breaking of at least one of scanning lines, signal lines, and capacitance lines in the circuit layer 30 due to a step difference.

When the interference-type color filter is used in the display device, the transmission wavelength band thereof varies depending on the incident angle of light. For example, the transmission wavelength band for obliquely incident light shifts to a wavelength band (blue) shorter than the transmission wavelength band for light which is incident from the front side. In the embodiment, the wavelength selective absorption layer 40 is stacked on the wavelength selective transmission layer 20 to prevent the color shift.

In addition, the directivity of light emitted from the illuminating unit 70 can increase to prevent the color shift. In this case, for example, a light diffusion layer (for example, a light scattering layer) is provided on the upper surface of the counter substrate 12. In this way, it is possible to increase the viewing angle which is narrowed due to the use of light with high directivity.

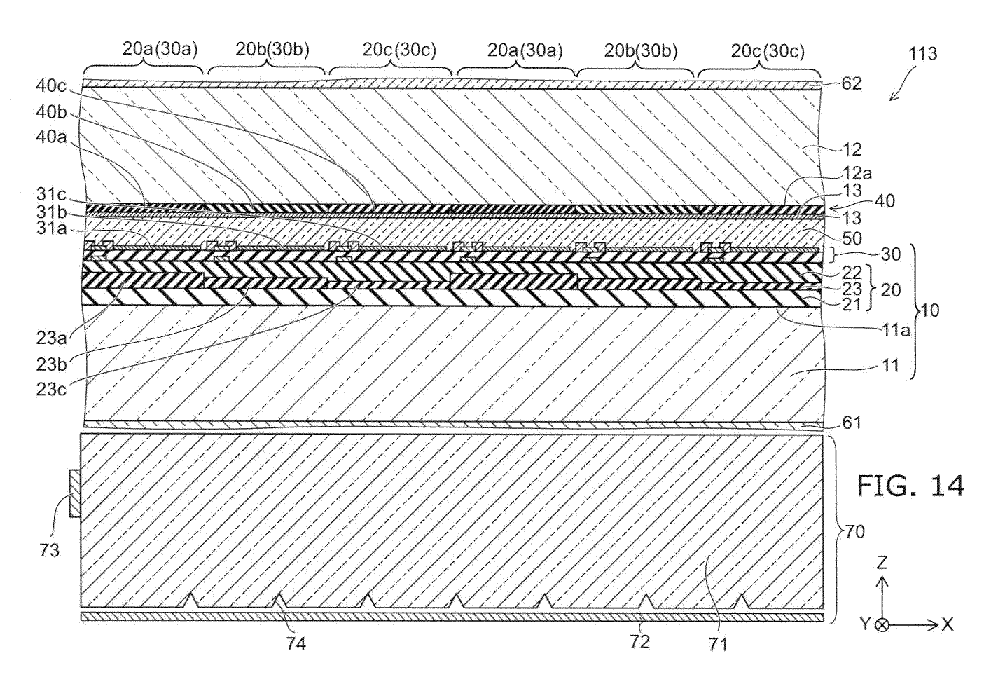

FIG. 14 is a schematic cross-sectional view illustrating the configuration of another display device according to the first embodiment. As shown in FIG. 14, in another display device 113 according to the embodiment, the interlayer film 29 is not provided. The upper reflecting layer 22 has a planarizing function.

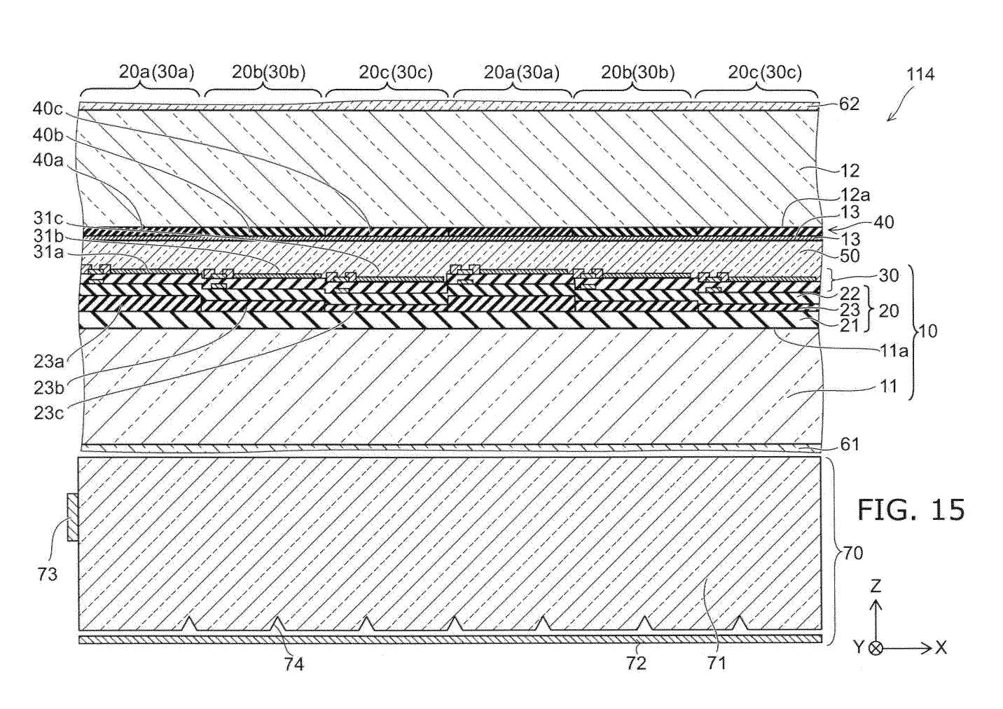

FIG. 15 is a schematic cross-sectional view illustrating the configuration of another display device according to the first embodiment. As shown in FIG. 15, in another display device 114 according to the embodiment, the interlayer film 29 is not provided. A step is formed for each pixel on the upper surface of the upper reflecting layer 22. For example, a plurality of pixel electrodes may be disposed at different positions in the Z-axis direction.

### Second Embodiment

Next, in a display device according to a second embodiment, components different from those in the first embodiment will be described.

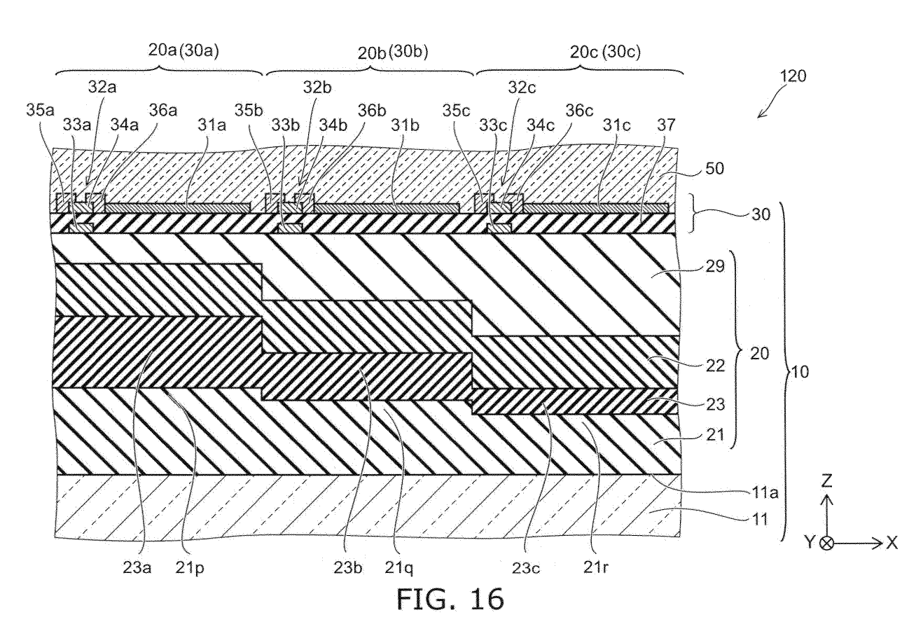

FIG. 16 is a schematic cross-sectional view illustrating the configuration of the display device according to the second embodiment.

As shown in FIG. 16, in a display device 120 according to the embodiment, the thickness of a portion (second portion 21q) of a lower reflecting layer 21 which faces a second spacer layer 23b is different from the thickness of a portion (first portion 21p) of the lower reflecting layer 21 which faces a first spacer layer 23a. Specifically, the thickness of the second portion 21q is less than that of the first portion 21p.

In this example, the thickness of a portion (third portion 21r) of the lower reflecting layer 21 which faces a third spacer layer 23c is different from the thickness of a portion (first portion 21p) of the lower reflecting layer 21 which faces the first spacer layer 23a. Specifically, the thickness of the third portion 21r is less than that of the first portion 21p. In this example, the thickness of the third portion 21r is less than that of the second portion 21q.

For example, the difference between the thicknesses occurs when over-etching is performed during the formation of the intermediate layer 23 having a plurality of regions with different thicknesses.

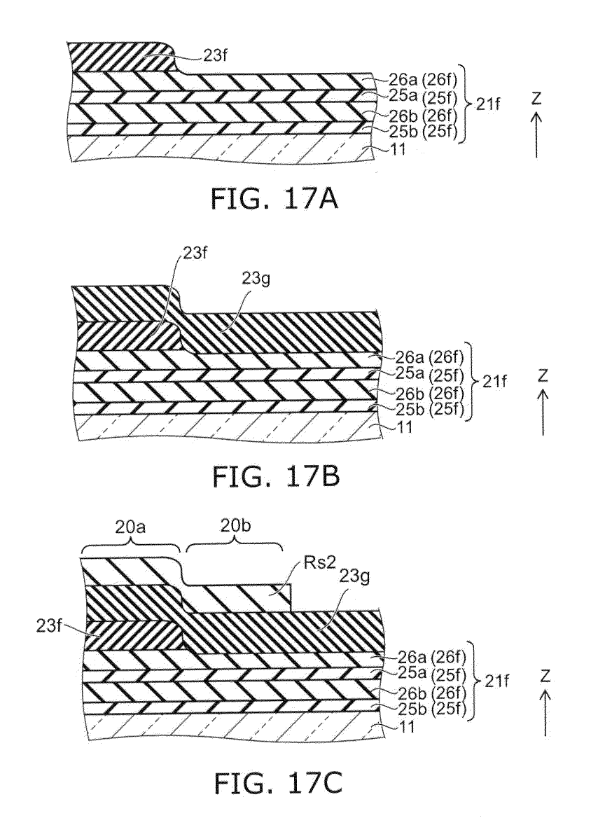

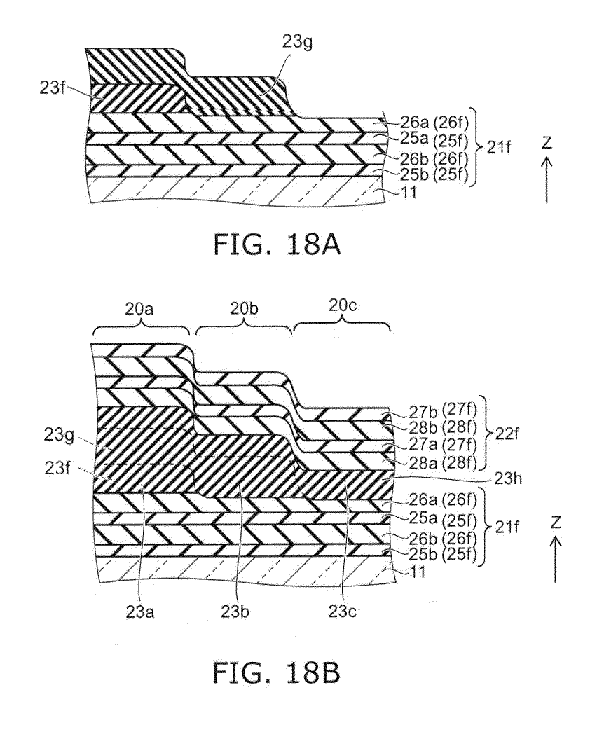

FIG. 17A, FIG. 17B, FIG. 17C, FIG. 18A and FIG. 18B are schematic cross-sectional views illustrating the processes of a method of manufacturing the display device according to the second embodiment.

As described in the first embodiment, a lower reflecting film 21f which will be the lower reflecting layer 21 is formed on a main surface 11a of a main base 11 and a first intermediate layer 23f which will be a portion (for example, the first spacer layer 23a) of the intermediate layer 23 is formed on the lower reflecting film 21f.

As shown in FIG. 17A, the first intermediate layer 23f is processed using a first mask member Rs1. In this case, over-etching is performed and the thickness of a portion of the lower reflecting film 21f which is not covered with the first mask member Rs1 is reduced. The over-etching makes it possible to sufficiently remove an unnecessary portion of the first intermediate layer 23f. As a result, the uniformity of the surface is improved.

As shown in FIG. 17B, a second intermediate layer 23g is formed. As shown in FIG. 17C, a second mask member Rs2 is formed. As shown in FIG. 18A, the second intermediate layer 23g is processed using the second mask member Rs2. In this case, if necessary, over-etching is performed and the thickness of a portion of the lower reflecting film 21f which is not covered with the second mask member Rs2 is reduced. In this way, it is possible to sufficiently remove an unnecessary portion of the second intermediate layer 23g. As a result, the uniformity of the surface is improved.

As shown in FIG. 18B, after the second mask member Rs2 is removed, a third intermediate layer 23h is formed. The upper reflecting layer 22 is formed on the second intermediate layer 23g (on the third intermediate layer 23h in this example). In addition, if necessary, an interlayer film 29 is formed on the upper reflecting layer 22. In this way, a wavelength selective transmission layer 20 is formed. Then, the display device 120 is formed through a predetermined process.

The inventors studied and proved that, in the above-mentioned process, for example, when at least one of the first intermediate layer 23f and the second intermediate layer 23g was removed, etching was non-uniformly performed and a residue was likely to be generated in the surface. In particular, this phenomenon is noticeable when the wavelength selective transmission layer 20 is made of a material with a high performance required for an underlayer (for example, an insulating property, in-plane uniformity, flatness, and productivity), such as a silicon oxide film, a silicon nitride film, and a silicon oxynitride film.

In other words, when a combination of materials with high etching selectivity is used, it is difficult to improve the function of the underlayer. In the embodiment, the wavelength selective transmission layer 20 functions as the underlayer to obtain high productivity. Therefore, the wavelength selective transmission layer 20 is made of a combination of materials which sufficiently function as the underlayer. As a result, in some cases, etching selectivity is insufficient.

In the embodiment, when at least one of the first intermediate layer 23f and the second intermediate layer 23g is removed, over-etching is performed in order to uniformly remove these films. In this way, a remaining film is not formed on the surface and the uniform wavelength selective transmission layer 20 is obtained.

In the embodiment, for example, a dielectric multi-layer film is used as the lower reflecting layer 21. For example, one of a first dielectric film 25 and a second dielectric film 26 comes into contact with the first spacer layer 23a and the second spacer layer 23b. In the above example, the second dielectric film 26 (specifically, a second dielectric film 26a) comes into contact with the first spacer layer 23a and the second spacer layer 23b.

The thickness of a portion (second portion 21q) of one (that is, the second dielectric film 26, specifically, the second dielectric film 26a) of the first dielectric film 25 and the second dielectric film 26 which comes into contact with the second spacer layer 23b is different from that of a portion (first portion 21p) of the second dielectric film 26 which comes into contact with the first spacer layer 23a. Specifically, for example, the thickness of the second portion 21q is less than that of the first portion 21p.

The inventors studied and proved that over-etching was preferably performed in regions other than the region corresponding to green. For example, when the first region 20a corresponds to green, over-etching is performed in at least one of the second region 20b and the third region 20c.

When over-etching is performed, a reduction in the thickness of the lower reflecting film 21f by over-etching is not necessarily uniform in the plane. When there is a large variation in the in-plane thickness in the region corresponding to green, a color change is likely to be perceived. In contrast, even when there is a large variation in the in-plane thickness in the region corresponding to red or blue, a color change is less likely to be perceived. It is considered that this phenomenon is caused by the visual characteristics of the human.

Therefore, the embodiment is designed such that the in-plane uniformity is as high as possible in the region corresponding to green.

In the embodiment, for example, the first wavelength band λa includes the wavelength of green and the second wavelength band λb includes the wavelength of at least one of red and blue. The thickness of a portion (second portion 21q) of the lower reflecting layer 21 which faces the second spacer layer 23b is less than that of a portion (first portion 21p) of the lower reflecting layer 21 which faces the first spacer layer 23a. That is, over-etching is performed in the second portion 21q.

In this way, the window of processing conditions is widened. Therefore, it is possible to improve, for example, yield and productivity is further improved. When the thickness of the lower reflecting layer 21 varies depending on regions, the optical characteristics of the transmission and reflection of the wavelength selective transmission layer 20 are changed. Design values are determined so as to compensate for the change and the change in the optical characteristics does not cause a problem in practice.

For example, the lower reflecting layer 21 includes a plurality of first dielectric films 25 and a plurality of second dielectric films 26 which are alternately stacked. The second dielectric film 26a (one of a plurality of second dielectric films 26) comes into contact with the intermediate layer 23 (for example, the second spacer layer 23b). The optical length of the plurality of first dielectric films 25 and the optical length of the plurality of second dielectric films 26 are set to (λ0)/4 (where λ0 is, for example, 535 nm corresponding to green light).

For example, over-etching is not performed in the following case. The thickness of the second dielectric film 26a which comes into contact with the second spacer layer 23b is L0, the peak wavelength of light passing through the second region 20b is λp, and the thickness of the second spacer layer 23b is W0. The refractive index of the second spacer layer 23b is n_{b}.

In this case, it is assumed that the thickness of the second dielectric film 26a is reduced from L0 to L1 by over-etching (L1<L0). In this case, the thickness of the second spacer layer 23b is set to be more than W0, which is a design value when over-etching is not performed. In this way, it is possible to compensate for a change in characteristics. In this case, the thickness of the second spacer layer 23b is set to be equal to or less than W1 max which is represented by the following expression:

W1max=W0+(1−L1/L0)×λ0/(4×n_{b}).

The peak of the wavelength of light passing through the wavelength selective transmission layer 20 is not more than λp, which is a design value. In this way, it is possible to compensate for a change in wavelength characteristics based on over-etching and maintain desired wavelength characteristics.

An example in which the thickness of the intermediate layer 23 is changed based on whether over-etching is performed will be described.

For example, as illustrated in FIG. 4, in the lower reflecting layer 21, the first dielectric film 25b, the second dielectric film 26b, the first dielectric film 25a, and the second dielectric film 26a are stacked in this order. In the upper reflecting layer 22, the fourth dielectric film 28a, the third dielectric film 27a, the fourth dielectric film 28b, and the third dielectric film 27b are stacked in this order.

For example, it is assumed that the first dielectric film 25b, the first dielectric film 25a, the third dielectric film 27a, and the third dielectric film 27b are made of SiN and the thickness of these films is 58.15 nm. It is assumed that the second dielectric film 26b, the second dielectric film 26a, the fourth dielectric film 28a, and the fourth dielectric film 28b are made of SiO₂ and the thickness of these films is 91.6 nm. It is assumed that the first spacer layer 23a, the second spacer layer 23b, and the third spacer layer 23c are made of SiN. It is assumed that the optical characteristics of SiO₂ and SiN are as illustrated in FIG. 5.

For example, when over-etching is not performed, the thickness of the first spacer layer 23a is designed to be 115 nm, the thickness of the second spacer layer 23b is designed to be 78 nm, and the thickness of the third spacer layer 23c is designed to be 30 nm. In this way, green light passes through the first region 20a, blue light passes through the second region 20b, and red light passes through the third region 20c.

For example, in one etching operation, it is assumed that an over-etching depth is 10 nm. In this case, the thickness of the second dielectric film 26a in the second region 20b is reduced from 91.6 nm to 81.6 nm and the thickness of the second dielectric film 26a in the third region 20c is reduced from 91.6 nm to 71.6 nm. In this case, the thickness of the second spacer layer 23b increases from 78 nm to 82.5 nm and the thickness of the third spacer layer 23c increases from 30 nm to 37 nm. The thickness of the first spacer layer 23a is 115 nm. In this way, even when over-etching is performed, substantially the same optical characteristics as those when over-etching is not performed are obtained.

In the above, liquid crystal is used as the light control layer 50. However, in the embodiment, the light control layer 50 may have any configuration. For example, a mechanical shutter using a micro-electro-mechanical system (MEMS) may be used as the light control layer 50.

According to the embodiments, a display device with high light use efficiency and high productivity and a method of manufacturing the display device are provided.

The embodiments of the invention have been described with reference to specific examples. However, the embodiments of invention are not limited to the specific examples. For example, the specific configurations of components, such as the main substrate, the main base, the wavelength selective transmission layer, the reflecting layer, the intermediate layer, the dielectric film, the spacer layer, the circuit layer, the pixel electrode, the switching element, the light control layer, the wavelength selective absorption layer, the counter substrate, and the illuminating unit of the display device are included in the scope of the invention as long as those skilled in the art can appropriately select the configurations from the known range, similarly implement the invention, and obtain the same effect as described above.

Further, any two or more components of the specific examples may be combined within the extent of technical feasibility and are included in the scope of the invention to the extent that the purport of the invention is included.

In addition, all of the display devices and methods of manufacturing the same which are obtained by those skilled in the art to appropriately change the design based on the display device and the method of manufacturing the same according to the above-described embodiments of the invention are included in the scope of the invention as long as they include the spirit of the invention.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A display device comprising:
a main substrate including
a main base having a main surface,
a wavelength selective transmission layer provided on the main surface, and
a circuit layer provided on the wavelength selective transmission layer; and
a light control layer stacked with the main substrate and having variable optical characteristics,
the wavelength selective transmission layer including:
a lower reflecting layer;
an upper reflecting layer provided on the lower reflecting layer;
a first spacer layer provided between the lower reflecting layer and the upper reflecting layer; and
a second spacer layer provided between the lower reflecting layer and the upper reflecting layer so as to be juxtaposed to the first spacer layer parallel to the main surface and having a thickness different from a thickness of the first spacer layer, and
the circuit layer including:
a first pixel electrode including a portion overlapping the first spacer layer, as viewed along a first direction perpendicular to the main surface;
a second pixel electrode including a portion overlapping the second spacer layer, as viewed along the first direction;
a first switching element connected to the first pixel electrode; and
a second switching element connected to the second pixel electrode.

2. The device according to claim 1, wherein
in a first region including the lower reflecting layer, the first spacer layer and the upper reflecting layer of the wavelength selective transmission layer, a light in a first wavelength band is transmitted and a light of a visible light in a wavelength band except the first wavelength band is reflected, and
in a second region including the lower reflecting layer, the second spacer layer and the upper reflecting layer of the wavelength selective transmissive layer, a light in a second wavelength band different from the first wavelength band is transmitted and a light of a visible light in a wavelength band except the second wavelength band.

3. The device according to claim 2, wherein
the first wavelength band includes a wavelength of green,
the second wavelength band includes a wavelength of at least one of red and blue, and
a thickness of a portion of the lower reflecting layer opposed to the second spacer layer is less than a thickness of a portion of the lower reflecting layer opposed to the first spacer layer.

4. The device according to claim 1,
wherein a thickness of a portion of the lower reflecting layer opposed to the second spacer layer is different from a thickness of a portion of the lower reflecting layer opposed to the first spacer layer.

5. The device according to claim 1, wherein
the lower reflecting layer includes:
a first dielectric film; and
a second dielectric film that is stacked with the first dielectric film in the first direction and having a refractive index different from a refractive of the first dielectric film.

6. The device according to claim 5, wherein
one of the first dielectric film and the second dielectric film contacts the first spacer layer and the second spacer layer, and
a thickness of a portion of the one contacting the second spacer layer is different from a thickness of a portion of the one contacting the first spacer layer.

7. The device according to claim 5, wherein
one of the first dielectric film and the second dielectric film contacts the first spacer layer and the second spacer layer, and
the refraction index of the one is lower than a refraction index of the first spacer layer and lower than a refractive index of the second spacer layer.

8. The device according to claim 5, wherein
the first dielectric film is provided in a plurality,
the second dielectric film is provided in a plurality, and
the plurality of first dielectric films and the plurality of second dielectric films are alternately stacked in the first direction.

9. The device according to claim 5, wherein
the first dielectric film and the second dielectric film include at least one of a silicon oxide, a silicon nitride, and a silicon oxynitride, and
a content of at least one of oxygen and nitrogen contained in the first dielectric film is different from a content of at least one of oxygen and nitrogen contained in the second dielectric film.

10. The device according to claim 1, further comprising:
a wavelength selective absorption layer stacked with the main substrate,
the wavelength selective absorption layer including:
a first absorption layer including a portion overlapping the first spacer layer, as viewed along the first direction; and
a second absorption layer including a portion overlapping the second spacer layer, as viewed along the first direction, and having an absorption spectrum different from an absorption spectrum of the first absorption layer,
in a first region including the lower reflecting layer, the first spacer layer, and the upper reflecting layer of the wavelength selective transmission layer, a light in a first wavelength band is transmitted and a light of a visible light in a wavelength band except the first wavelength band is reflected,
in a second region including the lower reflecting layer, the second spacer layer, and the upper reflecting layer of the wavelength selective transmission layer, a light in a second wavelength band different from the first wavelength band is transmitted and a light of a visible light in a wavelength band except the second wavelength band is reflected,
an absorptance of the light in the first wavelength band by the first absorption layer is less than an absorptance of the light of a visible light in the wavelength band except the first wavelength band by the first absorption layer, and
an absorptance of the light in the second wavelength band by the second absorption layer is less than an absorptance of the light of a visible light in the wavelength band except the second wavelength band by the second absorption layer.

11. The device according to claim 10, wherein the light control layer is disposed between the circuit layer and the wavelength selective absorption layer.

12. The device according to claim 10, wherein
the wavelength selective transmission layer includes a region provided between the lower reflecting layer and the upper reflecting layer and juxtaposed to a region in which the first spacer layer is provided and a region in which the second spacer layer is provided,
the circuit layer includes:
a third pixel electrode including a portion overlapping the juxtaposed region, as viewed along the first direction; and
a third switching element connected to the third pixel electrode,
the wavelength selective absorption layer further includes a third absorption layer including a portion overlapping the juxtaposed region, as viewed along the first direction, and having an absorption spectrum different from the absorption spectrums of the first and second absorption layers,
in the juxtaposed region of the wavelength selective transmission layer, a light in a third wavelength band different from the first wavelength band and the second wavelength band is transmitted and a light of a visible light in a wavelength band except the third wavelength band is reflected, and
an absorptance of the light in the third wavelength band by the third absorption layer is less than an absorptance of the light of a visible light in the wavelength band except the third wavelength band by the third absorption layer.

13. The device according to claim 12, wherein
the first wavelength band includes a green wavelength band,
the second wavelength band includes a blue wavelength band, and
third wavelength band includes a red wavelength band.

14. The device according to claim 1, further comprising:
an illuminating unit configured to emit an illumination light so as to be incident on the wavelength selective transmission layer in a direction from the wavelength selective transmission layer to the wavelength selective absorption layer,
the illumination light emitted from the illuminating unit is reflected at a portion of the wavelength selective transmission layer including the first spacer layer and at least a part of the reflected light is incident on a portion of the wavelength selective transmission layer including the second spacer layer.

15. The device according to claim 14, wherein
the illumination unit includes:
a light guide body;
a light source configured to emit a light to be incident on the light guide body; and
a traveling direction change portion changing a traveling direction of a light guided in the light guide body to be incident on the wavelength selective transmissive layer and having an unevenness shape.

16. The device according to claim 1,
wherein the light control layer includes a liquid crystal layer.

17. The device according to claim 1, wherein the first switching element and the second switching element include a thin film transistor including a semiconductor layer including amorphous silicon or polysilicon.

18. The device according to claim 1, wherein the wavelength selective transmissive layer includes at least one of a silicon oxide, a silicon nitride and a silicon oxynitride.

19. A method for manufacturing a display device including a main substrate including a main base having a main surface, a wavelength selective transmission layer provided on the main surface, and a circuit layer provided on the wavelength selective transmission layer, a wavelength selective absorption layer stacked with the main substrate, and a light control layer stacked with the wavelength selective absorption layer and having variable optical characteristics, the wavelength selective transmission layer including a lower reflecting layer, an upper reflecting layer provided on the lower reflecting layer, a first spacer layer provided between the lower reflecting layer and the upper reflecting layer, and a second spacer layer provided between the lower reflecting layer and the upper reflecting layer so as to be juxtaposed to the first spacer layer in a first plane parallel to the main surface and having a thickness different from a thickness of the first spacer layer, the circuit layer including a first pixel electrode including a portion overlapping the first spacer layer, as viewed along a first direction perpendicular to the main surface, a second pixel electrode including a portion overlapping the second spacer layer, as viewed along the first direction, a first switching element connected to the first pixel electrode, and a second switching element connected to the second pixel electrode, the wavelength selective absorption layer including a first absorption layer provided on the first pixel electrode and a second absorption layer provided on the second pixel electrode and having an absorption spectrum different from an absorption spectrum of the first absorption layer, the method comprising:
forming a lower reflecting film serving as the lower reflecting layer on the main surface of the main base;
forming a first intermediate layer serving as a part of the first spacer layer on the lower reflecting film;
forming a first mask member covering a first region of the first intermediate layer;
removing a portion of the first intermediate layer not covered with the first mask member and reducing a thickness of a portion of the lower reflecting film not covered with the first mask member using over-etching;
forming a second intermediate layer serving as another portion of the first spacer layer and at least a portion of the second spacer layer on the remaining first intermediate layer and the lower reflecting film after removing the first mask member;
forming the upper reflecting layer on the second intermediate layer; and
forming the circuit layer on the upper reflecting layer.

20. The method according to claim 19, further comprising:
forming a second mask member covering the first region and a second region different from the first region in the second intermediate layer after the forming the second intermediate layer and before the forming the upper reflecting layer;
removing a portion of the second intermediate layer not covered with the second mask member and reducing a thickness of a portion of the lower reflecting film not covered with the second mask member using over-etching; and
forming a third intermediate layer serving as another portion of the first spacer layer and a portion of the second spacer layer on the remaining second intermediate layer and the lower reflecting film after removing the second mask member,
the forming the upper reflecting layer including forming the upper reflecting layer on the third intermediate layer.
